(19) United States
(12) Patent Application Publication
(10) Pub. No.: US 2017/0365752 A1
(43) Pub. Date: Dec. 21, 2017

(54) CONVERSION ELEMENT, OPTOELECTRONIC SEMICONDUCTOR DEVICE AND METHOD FOR PRODUCING CONVERSION ELEMENTS

(71) Applicant: OSRAM Opto Semiconductors GmbH, Regensburg (DE)

(72) Inventors: Thomas SCHWARZ, Regensburg (DE); Frank SINGER, Regenstauf (DE); Stefan ILLEK, Donaustauf (DE); Michael ZITZLSPERGER, Regensburg (DE); Britta GOEOETZ, Regensburg (DE); Dominik SCHULTEN, Kelheim (DE)

(21) Appl. No.: 15/533,005

(22) PCT Filed: Dec. 4, 2015
(86) PCT No.: PCT/EP2015/078697

§ 371 Date: Jun. 2, 2017

(30) Foreign Application Priority Data
Dec. 5, 2014 (DE) 10 2014 117 983.8

(51) Int. Cl. H01L 33/50; H01L 33/48

(52) U.S. Cl. CPC H01L 33/505; H01L 33/486; H01L 33/507

(57) ABSTRACT

Disclosed is a conversion element (100). The conversion element (100) comprises: a conversion coating (16), which contains a wavelength-converting conversion material; a first encapsulation coating (30) on a first main surface (20) of the conversion coating, said first encapsulation coating having a thickness of between 10 μm and 500 μm; and a second encapsulation coating (32) on a second main surface (22) of the conversion coating, said second encapsulation coating having a thickness of between 0.1 μm and 20 μm. Also disclosed are an optoelectronic semiconductor component (200) and a method for producing conversion elements.

This patent application claims priority from German patent application DE 102014117983.8, the disclosure content of which is hereby included by reference.

A conversion element, an optoelectronic semiconductor device and a method for producing conversion elements are provided.

Conversion elements are known from the prior art which are configured to convert primary radiation of a first wavelength (for example generated in a semiconductor chip) into secondary radiation of a second, longer wavelength different from the first wavelength. Conversion elements often comprise a sensitive, wavelength-converting conversion material, which may be damaged and/or destroyed for example by oxidation on contact with for example oxygen and/or water.

One object to be achieved consists in providing a conversion element which has an increased service life.

This object is achieved inter alia by a conversion element, a method for producing a multiplicity of conversion elements and a semiconductor device according to the independent claims. Configurations and convenient aspects constitute the subject matter of the dependent claims.

A conversion element is provided. According to at least one embodiment, the conversion element has a conversion layer which comprises a wavelength-converting conversion material.

In this case, a wavelength-converting conversion material is distinguished in that the wavelength of an electromagnetic radiation emitted for example by a semiconductor chip is converted at the conversion material. The conversion element is hereby configured to convert primary radiation of a first wavelength (for example generated in a semiconductor chip) into secondary radiation of a second, longer wavelength different from the first wavelength.

The conversion layer comprises in particular a sensitive wavelength-converting conversion material. A sensitive conversion material is distinguished for example in that the conversion material may be damaged and/or destroyed for example by oxidation on contact with for example oxygen and/or water. Furthermore, the sensitive conversion material may react sensitively to temperature fluctuations and be impaired for example in its functionality by such temperature fluctuations.

According to at least one embodiment, the conversion layer is encapsulated on all sides. This means in particular that the conversion layer is encapsulated both on the two major faces and on its side faces. This all-round encapsulation ensures an increased service life for the conversion layer. According to at least one embodiment, the conversion element comprises a first encapsulation layer on a first major face of the conversion layer. The first encapsulation layer has a thickness of between 10 μm and 500 μm, preferably between 25 μm and 300 μm, for example between 50 μm and 200 μm.

According to at least one embodiment, the conversion element comprises a second encapsulation layer on a second major face of the conversion layer. The second encapsulation layer has a thickness of between 0.1 μm and 20 μm, preferably between 0.2 μm and 10 μm, for example between 0.5 μm and 5 μm.

The statement that a layer or an element is arranged or applied “on” or “over” another layer or another element may here and hereinafter mean that the one layer or the one element is arranged directly in direct mechanical and/or electrical contact with the other layer or the other element. It may moreover also mean that the one layer or the one element is arranged indirectly on or over the other layer or the other element. In this case, further layers and/or elements may then be arranged between the one layer and the other.

Preferably, both the first encapsulation layer and the second encapsulation layer contain an (in particular transparent) encapsulation material which differs from the conversion material. The encapsulation material is configured to protect the conversion layer from the effects of moisture and oxygen. For example, the encapsulation material may have a water vapor transmission rate which amounts to at most 1×10⁻³ g/m²/day, for example at most 3×10⁴ g/m²/day, preferably at most 1×10⁻⁶ g/m²/day, particularly preferably at most 1×10⁻⁸g/m²/day.

Because the conversion element may be separately encapsulated, i.e. encapsulation does not occur until a point at which the conversion element has already bean arranged in an optoelectronic semiconductor device, the conversion element may be precharacterized. In particular, a color location of the secondary radiation generatable by the conversion element may be measured. In a subsequent method step, the conversion element may be combined in an optoelectronic semiconductor device with a semiconductor chip which itself emits primary radiation of a suitable color location, whereby white light with the desired color properties may advantageously be generated.

According to at least one embodiment, the conversion material comprises wavelength-converting quantum dots. For example, the conversion layer comprises a matrix material (for example an acrylate), wherein the wavelength-converting quantum dots have been introduced into the matrix material.

Through the use of quantum dots as the conversion material, good color rendering is achieved, since the converted electromagnetic radiation is relatively narrowband and thus no mixing of different spectral colors arises. For example, the spectrum of the converted radiation has a wavelength width of at least 20 nm to at most 60 nm. This allows the generation of light whose color may be assigned very precisely to a region of the spectrum. In this way, a large color gamut may be achieved when using the conversion element in an optoelectronic semiconductor device of a backlighting apparatus.

The quantum dots are preferably nanoparticles, i.e. particles with a size in the nanometer range. The quantum dots comprise a semiconductor core, which has wavelength-converting characteristics. The semiconductor core may for example be formed with CdSe, CdS, InAs, CuInS₂, ZnSe (for example Mn-doped) and/or InP and for example doped. For applications with infrared radiation, the semiconductor core may for example be formed with CdTe, PbS, PbSe and/or GaAs and likewise for example doped. The semiconductor core may be encased in a plurality of layers. In other words, the semiconductor core may be completely or almost completely covered by further layers at its outer faces.

A first encasing layer of a quantum dot is for example formed with an inorganic material, such as for example ZnS, CdS and/or CdSe, and serves in creation of the quantum dot potential. The first encasing layer and the semiconductor core are almost completely enclosed at the exposed outer faces by at least one second encasing layer. The second layer may for example be formed with an organic material, such as for example cystamine or cysteine, and may serve to improve the solubility of the quantum dots in for example a matrix material and/or a solvent (amines, and sulfur-containing or phosphorus-containing organic compounds may also be used). In this case, it is possible for a spatially uniform distribution of the quantum dots in a matrix material to be improved as a result of the second encasing layer.

According to at least one embodiment of the conversion element, provision is made for side faces of the conversion element to bear traces of singulation.

According to at least one embodiment of the conversion element, provision is made for the first encapsulation layer to be formed by a carrier element of a glass or a plastics material. The carrier element may for example contain a borosilicate glass or consist of a borosilicate glass.

According to at least one embodiment of the conversion element, provision is made for the second encapsulation layer to comprise Al₂O₃, SiO₂, ZrO₂, TiO₂, Si₃N₄, siloxane, SiOₓN_{y} and/or a parylene or to consist of one of these materials. Preferably, the second encapsulation layer is formed by a coating method, for example with atomic layer deposition (ALD) and/or chemical vapor deposition (CVD) and/or sputtering. Chemical vapor deposition may also be plasma-enhanced.

According to at least one embodiment of the conversion element, provision is made for a frame element to be arranged on the first encapsulation layer, which frame layer laterally encloses the conversion layer. A lateral direction is here and hereinafter understood to mean a direction parallel to the main plane of extension of the conversion layer and/or of the first encapsulation layer and/or of the second encapsulation layer. Likewise, a vertical direction is understood to mean a direction perpendicular to said plane.

According to at least one embodiment of the conversion element, the first encapsulation layer and the frame element are of one-piece configuration. For example, the first encapsulation layer and the frame element may be formed by a trough-shaped or honeycomb-shaped element of glass or another transparent material.

According to at least one embodiment of the conversion element, the second encapsulation layer extends as far as over the side faces of the conversion layer and laterally encloses the conversion layer. The process steps which are necessary for forming a frame element are then omitted during production.

According to at least one embodiment, an optoelectronic semiconductor device comprises a semiconductor chip provided for generating electromagnetic radiation. The semiconductor chip in particular comprises a semiconductor body with an active region provided for generating electromagnetic radiation. The semiconductor body, in particular the active region, for example contains a III-V compound semiconductor material.

According to at least one embodiment of the optoelectronic semiconductor device, the semiconductor device comprises a package body which surrounds the semiconductor chip at least in a lateral direction.

According to at least one embodiment of the optoelectronic semiconductor device, a conversion element is arranged on the package body which comprises a wavelength-converting conversion material and is configured as described above.

For example, the semiconductor device is provided for generating mixed light, in particular mixed light which appears white to the human eye. For example, blue electromagnetic radiation is converted by the conversion element at least partially or completely into red and/or green radiation.

According to at least one embodiment of the optoelectronic semiconductor device, the semiconductor device comprises on a back surface two contacts for contacting the semiconductor chip. The back surface of the semiconductor device is understood to mean the side of the semiconductor device which is remote from the conversion element when viewed from the semiconductor chip.

According to at least one embodiment of the optoelectronic semiconductor device, the semiconductor device additionally comprises a leadframe. The two contacts are preferably formed on the back surface of the semiconductor device by parts of the leadframe.

According to at least one embodiment of the optoelectronic semiconductor device, the conversion element is arranged in such a way on the package body that the first encapsulation layer is remote from the semiconductor chip when viewed from the conversion layer.

According to at least one embodiment of the optoelectronic semiconductor device, the package body comprises an outer wall region which laterally encloses the conversion element at least in part.

A method is provided for producing a multiplicity of conversion elements.

According to at least one embodiment of the method, the method comprises a step in which a carrier assembly is provided which may for example contain a glass or a plastics material or consist of one of these materials. The carrier assembly may have a thickness of between 10 μm and 500 μm, preferably between 25 μm and 300 μm, for example between 50 μm and 200 μm.

According to at least one embodiment of the method, the method comprises a step in which a multiplicity of conversion layers is formed on the carrier assembly, wherein the conversion layers are spaced from one another in a lateral direction and are each arranged with a first major face on the carrier assembly.

According to at least one embodiment of the method, the method comprises a step in which a coating is formed at least on every second major face of the multiplicity of conversion layers, preferably with a material which differs from the material of the carrier assembly. The coating may for example comprise Al₂O₃, SiO₂, ZrO₂, TiO₂, Si₃N₄, siloxane, SiOₓN_{y} and/or a parylene or consist of one of these materials. It is preferable if a coating method is used here, such as for example atomic layer deposition (ALD) and/or chemical vapor deposition (CVD) and/or sputtering. Chemical vapor deposition may also be plasma-enhanced. The coating has a thickness of between 0.1 μm and 20 μm, preferably between 0.2 μm and 10 μm, for example between 0.5 μm and 5 μm.

According to at least one embodiment of the method, said method comprises a step in which the carrier assembly is singulated into a multiplicity of conversion elements, wherein each conversion element comprises at least one conversion layer, one part of the carrier assembly as first encapsulation layer and one part of the coating as second encapsulation layer. A consequence of singulation is that side faces of the resultant conversion elements bear traces of singulation.

According to at least one embodiment of the method, the method comprises a step in which, prior to formation of the multiplicity of conversion layers on the carrier assembly, a grid structure is formed on the carrier assembly. The grid structure comprises a multiplicity of openings arranged in a matrix. The carrier assembly is exposed in the region of each of the openings. One of the conversion layers is then formed in each of the openings. On singulation, the grid structure is cut through in such a way that each conversion element comprises a part of the grid structure as a frame element laterally enclosing the conversion layer.

According to at least one embodiment of the method, said method comprises a step in which the grid structure is formed by fastening a sheet element to the carrier assembly and forming openings in the sheet element. The sheet element may consist for example of silicon and be fastened to the carrier assembly by an anodic bonding process. The openings may then be etched. It is alternatively possible to form the openings in the sheet element before the sheet element is fastened on the carrier assembly.

According to at least one embodiment of the method, said method comprises a step in which the grid structure is formed by providing a carrier structure in which recesses are formed in a matrix arrangement. A first part of the carrier structure here forms the carrier assembly, and a second part the grid structure, for the purposes of the present application.

According to at least one embodiment of the method, regions of the carrier assembly which are arranged between the laterally spaced conversion layers remain uncovered, in particular free of a grid structure configured as described above.

Advantageously, use of the above method results in impermeable and complete encapsulation of the conversion layers in the resultant conversion elements, while all or at least most of the production steps proceed at carrier assembly level, which allows for particularly efficient fabrication of the conversion elements. At the same time, optoelectronic semiconductor devices with conversion elements produced in this way have a particularly shallow and compact design, whereby they are suitable for example for use in backlighting apparatuses.

The above-described method for producing conversion elements is particularly suitable for producing the conversion element according to the invention. Features listed in connection with the method may therefore also be used for the conversion element or vice versa.

Further features, configurations and convenient aspects are revealed by the following description of the exemplary embodiments in conjunction with the figures.

Identical, similar or identically acting elements are provided with the same reference numerals in the figures.

The figures and the size ratios of the elements illustrated in the figures relative to one another are not to be regarded as being to scale. Rather, individual elements and in particular layer thicknesses may be illustrated on an exaggeratedly large scale for greater ease of depiction and/or better comprehension.

### IN THE FIGURES

FIGS. 1 to 7 and 8 to 13 each show an exemplary embodiment of a method for producing conversion elements on the basis of intermediate steps shown in each case in schematic sectional view;

FIGS. 14 to 19 each show an exemplary embodiment of a conversion element; and

FIGS. 20 to 29 each show an exemplary embodiment of an optoelectronic device.

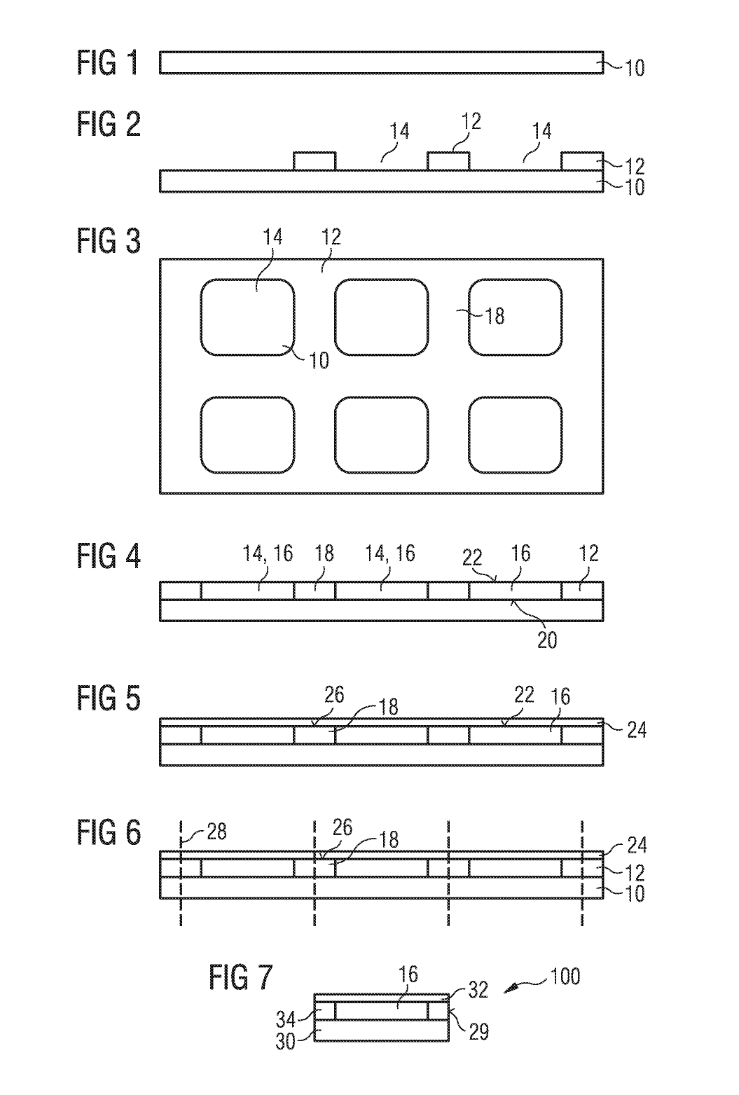

FIGS. 1 to 7 show a first exemplary embodiment of a method for producing a multiplicity of conversion elements.

In the method step shown in FIG. 1, a carrier assembly 10 for example of glass is provided, which has a thickness of between 50 μm and 200 μm.

In the method step shown in FIG. 2 a grid structure 12 is formed on the carrier assembly 10. FIG. 3 shows the assembly shown in FIG. 2 in plan view. The grid structure 12 comprises a multiplicity of openings 14 arranged in a matrix. The carrier assembly 10 is exposed in the region of each of the openings 14.

A conversion layer 16 is then formed in each of the openings 14 (FIG. 4). Partitions 18 formed by the grid structure 12 are arranged between two adjacent conversion layers 16, such that the conversion layers 16 are spaced laterally from one another. Each of the conversion layers 16 comprises a first major face 20 and a second major face 22 opposite the first major face 20. The first major face 20 of each of the conversion layers 16 adjoins the carrier assembly 10.

In the method step shown in FIG. 5, a coating 24 is formed which in each case covers the second major face 22 of each conversion layer 16 and the tops 26 of the partitions 18 remote from the carrier assembly 10. The coating 24 may for example consist of a parylene and have a thickness of between 0.5 μm and 5 μm.

In the method step shown in FIG. 6, the carrier assembly 10 and the grid structure 12 are singulated into a multiplicity of conversion elements 100. To this end, the carrier assembly 10 is cut through in the region of the partitions 18 along singulation lines 28. This may for example proceed mechanically, for instance by means of sawing, chemically, for example by means of etching, and/or by means of coherent radiation, for instance by laser ablation.

Each of the resultant conversion elements 100 comprises at least one conversion layer 16, one part of the carrier assembly 10 as a first encapsulation layer 30 and one part of the coating 24 as a second encapsulation layer 32 (FIG. 7). Moreover, each conversion element 100 comprises parts of the cut-through partitions 18 of the grid structure 12. These form a frame element 34 which laterally encloses and thereby encapsulates the conversion layer. A consequence of singulation is that side faces 29 of the resultant conversion elements 100 bear traces of singulation.

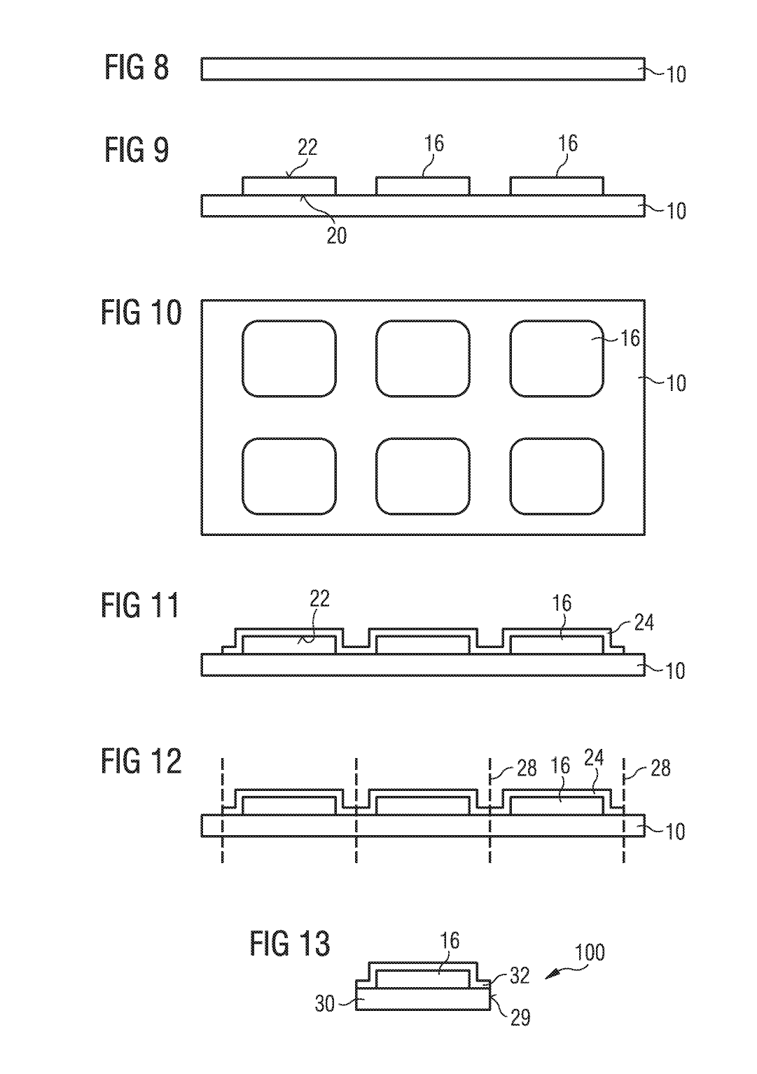

FIGS. 8 to 13 show a second exemplary embodiment of a method for producing a multiplicity of conversion elements.

In the method step shown in FIG. 8, a carrier assembly 10 for example of glass is again provided.

In the method step shown in FIG. 9 the multiplicity of conversion layers 16 is formed on the carrier assembly 10 by a printing method such as screen printing, wherein the conversion layers 16 are spaced apart from one another in a lateral direction and are each arranged with their first major face 20 on the carrier assembly 10. In this case, regions of the carrier assembly 10 which are arranged between the laterally spaced conversion layers 16 remain uncovered, in particular free of the grid structure shown in FIGS. 2 and 3. FIG. 10 shows the assembly shown in FIG. 9 in plan view.

In the method step shown in FIG. 11, a coating 24 is formed which in each case covers the second major face 22 of each conversion layer 16 and the uncovered regions of the carrier assembly 10.

In the method step shown in FIG. 12, the carrier assembly 10 is singulated into a multiplicity of conversion elements 100. Each of the resultant conversion elements 100 again comprises at least one conversion layer 16, one part of the carrier assembly 10 as a first encapsulation layer 30 and one part of the coating 24 as a second encapsulation layer 32 (FIG. 13). As in the first exemplary embodiment, the side faces 29 of the resultant conversion elements 100 bear traces of singulation.

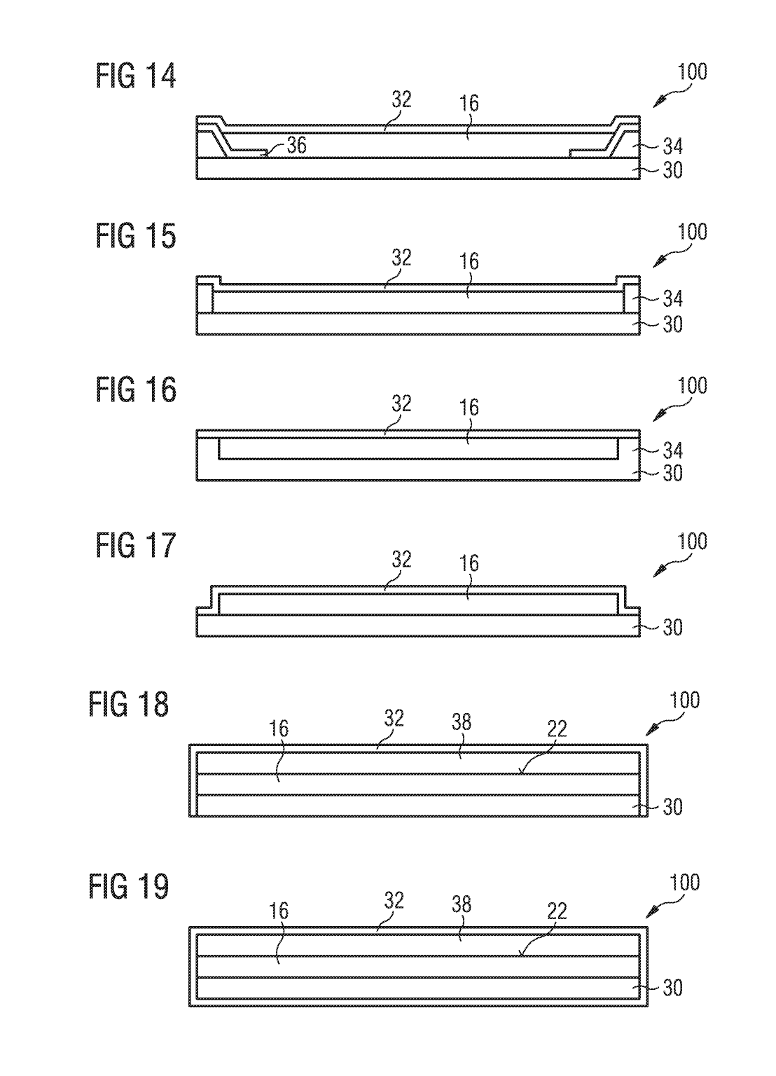

FIGS. 14 to 19 each show exemplary embodiments of conversion elements.

FIG. 14 shows an exemplary embodiment of a conversion element 100 which is produced using a method which comprises substantially the method steps shown in FIGS. 1-7.

In this case, a grid structure is formed in that a sheet element of silicon is fastened to the carrier assembly using an anodic bonding process and openings are formed in the sheet element by an anisotropic etching process (not shown).

The frame element 34 of the finished conversion element 100 consists of silicon and, together with the first encapsulation layer 30, forms a cavity in which the conversion layer 16 is arranged. In addition, the conversion element 100 comprises a reflective layer 36, which covers the frame element 34 and thereby prevents absorption of electromagnetic radiation by the material of the frame element 34. Restriction of the effective aperture may moreover be achieved, which is desired in some applications. The reflective layer 36 may take the form of a dielectric mirror or comprise a reflective material such as silver or aluminum.

FIG. 15 shows a further exemplary embodiment of a conversion element 100 which is produced using a method which comprises substantially the method steps shown in FIGS. 1-7.

In this case, a grid structure of a transparent or reflective (in particular highly reflective) material is formed, for example from an inorganic-organic hybrid polymer, a silicone or a metal. The frame element 34 of the finished conversion element 100 consequently consists of one of the stated materials and, together with the first encapsulation layer 30, again forms a cavity in which the conversion layer 16 is arranged.

In further exemplary embodiments not described in any greater detail, the cavity according to FIGS. 14 and 15, in which the conversion layer 16 is arranged, may also be produced using one of the following material combinations: glass-Kovar, glass-aluminum, quartz-metal. In this respect, the former material in each case is in particular a material which the first encapsulation layer 30 comprises or of which it consists. In addition, the latter material in each case is in particular a material which the frame element 34 comprises or of which it consists. Kovar is a material brand belonging to CRS Holdings Inc., Delaware. In particular, alloys are designated thereby which have a low coefficient of thermal expansion, typically for instance 5 ppm/K.

FIG. 16 shows a further exemplary embodiment of a conversion element 100 which is produced using a method which comprises substantially the method steps shown in FIGS. 1-7.

Unlike in the exemplary embodiments shown in FIGS. 14 and 15, a grid structure is formed by providing a carrier structure of glass in which recesses are formed in a matrix arrangement (not shown). To this end, the carrier structure of glass may be isotropically or anisotropically etched, sandblasted or pressed. A first part of the carrier structure here forms the carrier assembly, and a second part the grid structure, for the purposes of the present application. Consequently, the first encapsulation layer 30 and the frame element 34 are formed in one piece in the finished conversion element 100.

FIG. 17 shows a further exemplary embodiment of a conversion element 100 which is produced using a method which comprises substantially the method steps shown in FIGS. 8-13. In this embodiment of the conversion element, the second encapsulation layer 32 extends as far as over the side faces of the conversion layer 16 and laterally encloses the latter. Unlike in the exemplary embodiments shown in FIGS. 14 to 16, the process steps which are necessary for forming a frame element are omitted during production.

FIGS. 18 and 19 show further exemplary embodiments of a conversion element 100. Unlike in the exemplary embodiments shown in FIGS. 14 to 17, the conversion element 100 comprises a third encapsulation layer 38, which is arranged on the second major face 22 of the conversion layer 16. The first encapsulation layer 30 and the third encapsulation layer 38 preferably consist of the same material, for example of glass or plastics material, in particular of a plastics film. The first encapsulation layer 30, the conversion layer 16 and the third encapsulation layer 38 may in particular jointly form a film sandwich. The two exemplary embodiments shown in FIGS. 18 and 19 differ in that the second encapsulation layer 32 is applied either from just one side or from both sides. In the exemplary embodiment shown in FIG. 19, it also covers the side of the first encapsulation layer 30 remote from the conversion layer 16.

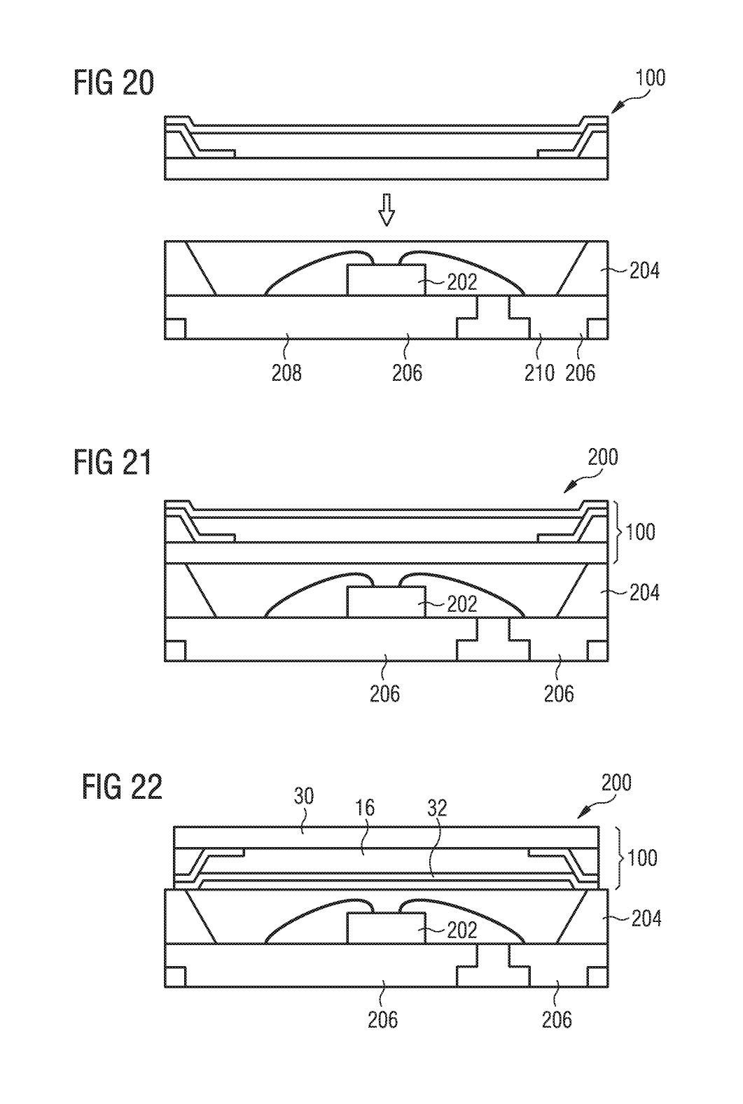

FIGS. 20 and 21 show an exemplary embodiment of an optoelectronic semiconductor device designated overall as 200. The optoelectronic semiconductor device 200 comprises a semiconductor chip 202 provided for generating electromagnetic radiation. Furthermore, the semiconductor device 200 comprises a package body 204 which surrounds the semiconductor chip 202 at least in a lateral direction. A conversion element 100 which corresponds to the embodiment shown in FIG. 14 is arranged on the package body 204.

The semiconductor device 200 is provided for generating mixed light, in particular mixed light which appears white to the human eye. For example, blue electromagnetic radiation is converted by the conversion element 100 at least partially or completely into red and/or green radiation.

The semiconductor device further comprises a leadframe 206, wherein two contacts 208, 210 are formed on the back surface of the semiconductor device 200 by parts of the leadframe 206.

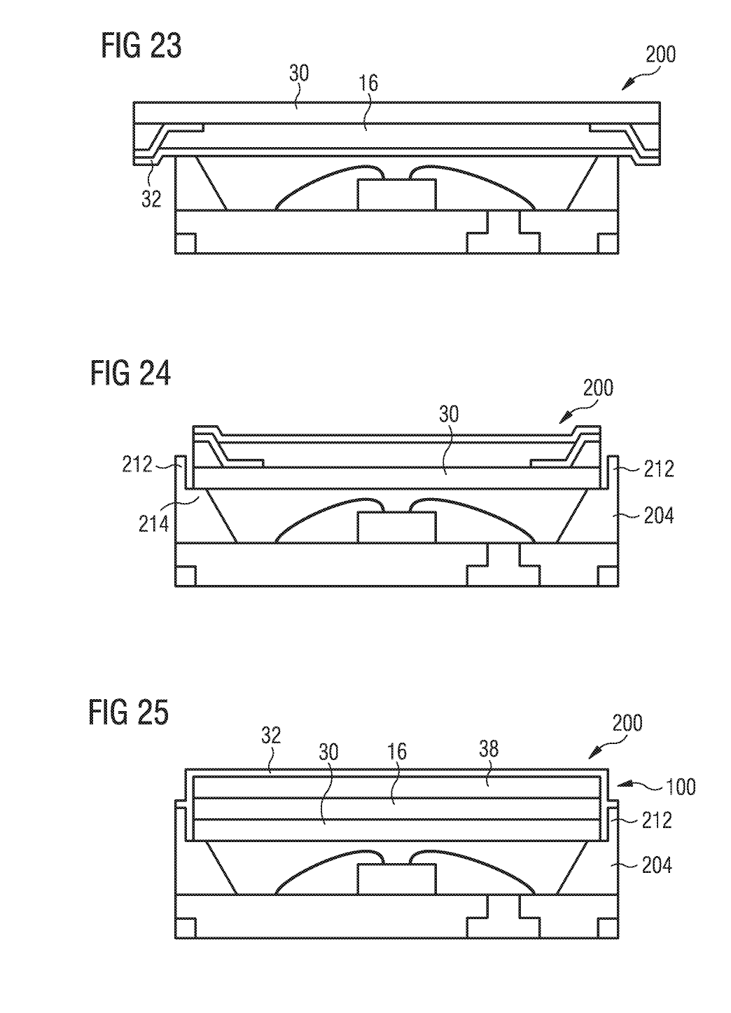

FIGS. 22 and 23 show two further exemplary embodiments of an optoelectronic semiconductor device.

Unlike in the exemplary embodiment shown in FIGS. 20 and 21, the conversion element 100 is arranged in such a way on the package body 204 that the first (thicker) encapsulation layer 30 is remote from the semiconductor chip when viewed from the conversion layer 16. This ensures that less blue light may exit at the sides of the optoelectronic semiconductor device due to waveguide effects, i.e. color non-uniformities (“blue piping”), which are attributable to unconverted primary radiation being able to leave the component past the conversion layer, are reduced.

Blue light can only pass outwards through the second encapsulation layer 32, which has only a small thickness. In the exemplary embodiment shown in FIG. 23, light may additionally pass outwards from the conversion layer 16. However, in this case the light is converted or white light.

FIG. 24 shows a further exemplary embodiment of an optoelectronic semiconductor device.

Unlike in the exemplary embodiment shown in FIGS. 20 and 21, the package body 204 comprises an outer wall region 212 which encloses the conversion element 100 laterally at least in part. In the present exemplary embodiment the package body 204 comprises a stepped cross-section. In this way, a base 214 is formed, on which the conversion element 100 may be arranged. Blue light passing through the first encapsulation layer 30 and exiting at the side faces thereof is hindered by absorption or reflection at the outer wall region 212 on outlet from the package body 204.

FIG. 25 shows a further exemplary embodiment of an optoelectronic semiconductor device.

Unlike in the exemplary embodiment shown in FIG. 24, the semiconductor device 200 comprises a conversion element 100 according to the exemplary embodiment shown in FIG. 18. The second encapsulation layer 32 is not formed until a point at which the sandwich formed by the first encapsulation layer 30, the conversion layer 16 and the third encapsulation layer 38 has been arranged on the package body 204. Accordingly, the second encapsulation layer 32 also covers a part of the outer wall region 212.

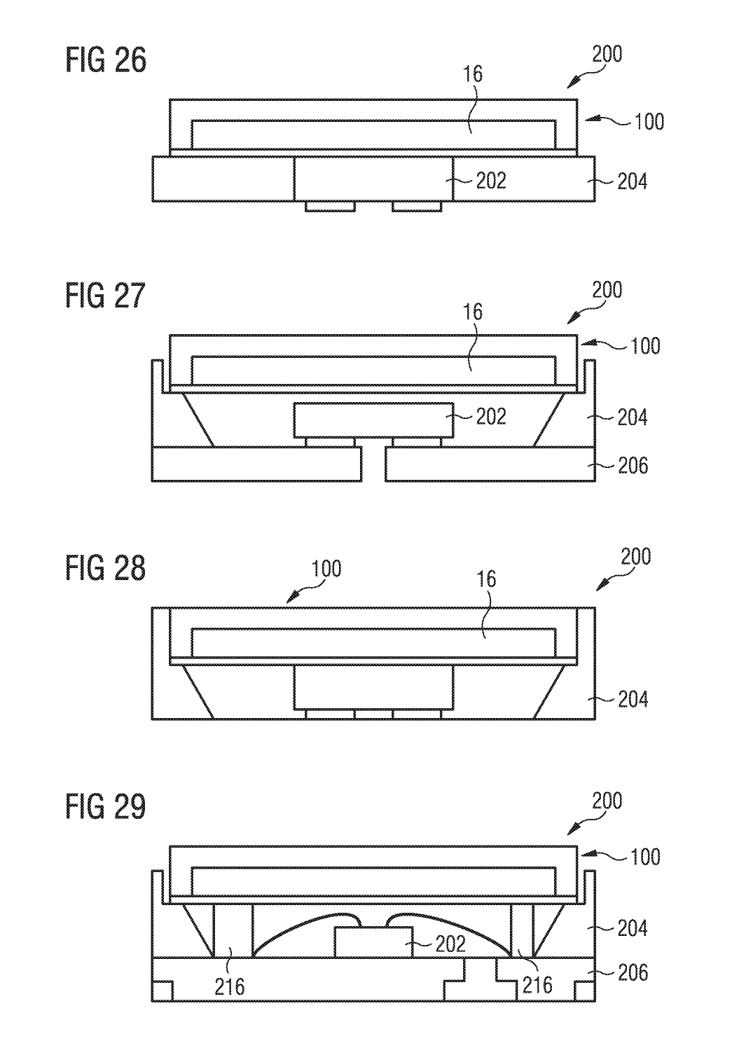

FIGS. 26 to 29 show four further exemplary embodiments of an optoelectronic semiconductor device.

Unlike in the exemplary embodiments shown in FIGS. 20 to 25, other types of semiconductor chips and package bodies are used. This illustrates that the invention is not limited to the arrangements shown in FIGS. 20 to 25, in particular to the use of a leadframe or of bonding wires for supplying electricity to the semiconductor chip. FIG. 26 shows an arrangement with a semiconductor chip 202 which takes the form of a sapphire flip chip or of a structure without top contacts, FIG. 27 shows an arrangement in which the semiconductor chip 202 is surrounded laterally by air and is in direct contact with the conversion element 100 or at least is arranged very close thereto, and FIG. 28 shows an optoelectronic device 200 in which the package body 204 is formed by compression molding or by film assisted transfer molding. In the arrangement shown in FIG. 29, thermal vias 216 are provided, which are arranged between the conversion element 100 and the leadframe 206 and ensure efficient heat dissipation from the conversion element 100.

The invention is not restricted by the description given with reference to the exemplary embodiments. Rather, the invention encompasses any novel feature and any combination of features, including in particular any combination of features in the claims, even if this feature or this combination is not itself explicitly indicated in the claims or the exemplary embodiments.

1. Conversion element comprising
a conversion layer, which comprises a wavelength-converting conversion material,
a first encapsulation layer on a first major face of the conversion layer, wherein the first encapsulation layer has a thickness of between 10 μm and 500 μm,
a second encapsulation layer on a second major face of the conversion layer, wherein the second encapsulation layer has a thickness of between 0.1 μm and 20 μm, and wherein the second encapsulation layer comprises Al₂O₃, SiO₂, ZrO₂, TiO₂, Si₃N₄, siloxane, SiOₓN_{y} and/or a parylene or consists of one of these materials.

2. Conversion element according to claim 1, wherein the conversion material comprises wavelength-converting quantum dots.

3. Conversion element according to claim 1, wherein side faces of the conversion element bear traces of singulation.

4. Conversion element according to claim 1, wherein the first encapsulation layer is formed by a carrier element of a glass or a plastics material.

5. Conversion element according to claim 1, wherein a frame element is arranged on the first encapsulation layer, which frame element laterally encloses the conversion layer.

6. Conversion element according to claim 5, wherein the first encapsulation layer and the frame element are configured in one piece.

7. Conversion element according to claim 1, wherein the second encapsulation layer extends as far as over the side faces of the conversion layer and laterally encloses the conversion layer.

8. Conversion element according to claim 1, wherein the conversion layer is encapsulated on all sides.

9. Optoelectronic semiconductor device having a conversion element according to claim 1, wherein
the semiconductor device comprises a semiconductor chip provided for generating electromagnetic radiation;
the semiconductor device comprises a package body which surrounds the semiconductor chip at least in a lateral direction; and
the conversion element is arranged on the package body.

10. Optoelectronic semiconductor device according to claim 9, wherein the conversion element is arranged in such a way on the package body that the first encapsulation layer is remote from the semiconductor chip when viewed from the conversion layer.

11. Optoelectronic semiconductor device according to claim 9, wherein the package body comprises an outer wall region which laterally encloses the conversion element at least in part.

12. Method for producing a multiplicity of conversion elements according to claim 1, having the steps:
a) providing a carrier assembly,
) forming a multiplicity of conversion layers on the carrier assembly, wherein the conversion layers are spaced from one another in a lateral direction and are each arranged with a first major face on the carrier assembly;
c) forming a coating at least on every second major face of the multiplicity of conversion layers with a material which differs from the material of the carrier assembly; and
d) singulating the carrier assembly into a multiplicity of conversion elements, wherein each conversion element comprises at least one conversion layer, one part of the carrier assembly as first encapsulation layer and one part of the coating as second encapsulation layer.

13. Method according to claim 12, in which, before performing step b), a grid structure is formed on the carrier assembly which comprises a multiplicity of openings arranged in a matrix, the carrier assembly being exposed in the region of each of the openings, the multiplicity of conversion layers are formed within the openings in step b), and the grid structure is cut through in step d) in such a way that each conversion element comprises a part of the grid structure as frame element which laterally encloses the conversion layer.

14. Method according to claim 13, in which the grid structure is formed by fastening a sheet element to the carrier assembly and forming openings in the sheet element.

15. Method according to claim 12, in which the grid structure is formed by providing a carrier structure in which recesses are formed in a matrix arrangement.

16. Conversion element comprising
a conversion layer, which comprises a wavelength-converting conversion material,
a first encapsulation layer on a first major face of the conversion layer, wherein the first encapsulation layer has a thickness of between 10 μm and 500 μm,
a second encapsulation layer on a second major face of the conversion layer, wherein the second encapsulation layer has a thickness of between 0.1 μm and 20 μm, and wherein the second encapsulation layer comprises Al₂O₃, SiO₂, ZrO₂, TiO₂, Si₃N₄, siloxane, SiOₓN_{y} and/or a parylene or consists of one of these materials,
a frame element, which frame element is arranged on the first encapsulation layer and which frame element laterally encloses the conversion layer.
